(19) United States
(12) Patent Application Publication
(10) Pub. No.: US 2025/0159962 A1
(43) Pub. Date: May 15, 2025

(54) SEMICONDUCTOR DEVICE AND METHOD OF FABRICATING THE SAME

(71) Applicant: Samsung Electronics Co., Ltd., Suwon-si (KR)

(72) Inventors: Hee Chan Song, Suwon-si (KR); Dohyung Kim, Suwon-si (KR); Dongsoo Lee, Suwon-si (KR); Hyeji Lee, Suwon-si (KR); Philjong Song, Suwon-si (KR); Yonghyuk Choi, Suwon-si (KR)

(21) Appl. No.: 18/670,794

(22) Filed: May 22, 2024

(30) Foreign Application Priority Data
Nov. 10, 2023 (KR) 10-2023-0155754

(51) Int. Cl. H01L 29/423

(52) U.S. Cl. CPC H10D 64/517; H10D 64/513; H10D 64/514

(57) ABSTRACT

A semiconductor device includes a substrate having a first active region and a second active region, a first gate conductive pattern that extends conformally in a first recess in the first active region, and a second gate conductive pattern that at least partially fills a second recess in the second active region. The first gate conductive pattern has a first thickness in a horizontal direction on an inner lateral surface of the first recess. The second gate conductive pattern has a second thickness in the horizontal direction on an inner lateral surface of the second recess. The first thickness is less than the second thickness.

### CROSS-REFERENCE TO RELATED APPLICATION

This U.S. nonprovisional application claims priority under 35 U.S.C. § 119 to Korean Patent Application No. 10-2023-0155754 filed on Nov. 10, 2023, in the Korean Intellectual Property Office, the disclosure of which is hereby incorporated by reference in its entirety.

The present inventive concepts relate to a semiconductor, and more particularly, to a semiconductor device and a method of fabricating the same.

### BACKGROUND

Semiconductor devices may have an important role in the electronic industry because of their small size, multi-functionality, and/or low fabrication cost. Semiconductor devices may be categorized as semiconductor memory devices storing logic data, semiconductor logic devices processing operations of logic data, and hybrid semiconductor devices having both memory and logic elements.

High speed and low consumption of electronic products may require that semiconductor devices embedded in the electronic products should have high operating speed and/or lower operating voltage. To meet these and other demands, semiconductor devices have been more highly integrated. Therefore, various research been conducted for increasing the reliability of semiconductor devices.

### SUMMARY

Some embodiments of the present inventive concepts provide a semiconductor device with improved electrical properties. The present inventive concepts are not limited to those mentioned herein, and other embodiments will be clearly understood to those skilled in the art from the following description.

According to some embodiments of the present inventive concepts, a semiconductor device may comprise: a substrate that includes a first active region and a second active region; a first gate conductive pattern that extends conformally in a first recess in the first active region; and a second gate conductive pattern that at least partially fills a second recess in the second active region. The first gate conductive pattern may have a first thickness in a horizontal direction on an inner lateral surface of the first recess. The second gate conductive pattern may have a second thickness in the horizontal direction on an inner lateral surface of the second recess. The first thickness may be less than the second thickness.

According to some embodiments of the present inventive concepts, a semiconductor device may comprise: a substrate that includes a first active region and a second active region; a first gate conductive pattern that extends conformally in a first recess of the first active region; and a second gate conductive pattern that at least partially fills a second recess of the second active region. The first gate conductive pattern may include a first p-type conductive pattern and a first n-type conductive pattern that are sequentially stacked and extend conformally in the first recess. The second gate conductive pattern may include a second p-type conductive pattern that extends conformally in the second recess of the second active region and a second n-type conductive pattern that is on the second p-type conductive pattern and at least partially fills a portion of the second recess that is unoccupied by the second p-type conductive pattern. A first work function of the first gate conductive pattern may be less than a second work function of the second gate conductive pattern.

According to some embodiments of the present inventive concepts, a semiconductor device may comprise: a substrate that includes a cell area and a peripheral area, the substrate including a first active region and a second active region on the peripheral area; a first gate conductive pattern that extends conformally in a first recess in the first active region; a second gate conductive pattern that at least partially fills a second recess in the second active region; first and second lower gate electrodes on the first and second conductive patterns, respectively; first and second upper gate electrode on the first and second lower gate electrodes, respectively; first and second barrier patterns between the first and second lower gate electrodes and the first and second upper gate electrodes, respectively; and first and second capping patterns on top surfaces of the first and second upper gate electrodes, respectively. The first gate conductive pattern may have a first thickness in a horizontal direction on an inner lateral surface of the first recess. The second gate conductive pattern may have a second thickness in the horizontal direction on an inner lateral surface of the second recess. The first thickness may be less than the second thickness.

### BRIEF DESCRIPTION OF DRAWINGS

FIG. 1 illustrates a plan view showing a semiconductor device according to some embodiments of the present inventive concepts.

FIG. 2 illustrates an enlarged view showing section P1 of FIG. 1.

FIGS. 3A, 3B, 3C, and 3D illustrate cross-sectional views taken along lines A-A′, B-B′, C-C′, and D-D′ of FIG. 2, respectively.

FIGS. 4A and 4B illustrate enlarged views showing section P2 of FIG. 3A.

FIGS. 5A, 5B, 5C, 5D, 6, 7, 8, 9, 10A, 10B, 10C, and 10D illustrate diagrams showing a method of fabricating a semiconductor device according to some embodiments of the present inventive concepts.

### DETAILED DESCRIPTION OF EMBODIMENTS

Some embodiments of the present inventive concepts will now be described in detail with reference to the accompanying drawings to aid in clearly explaining the present inventive concepts. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

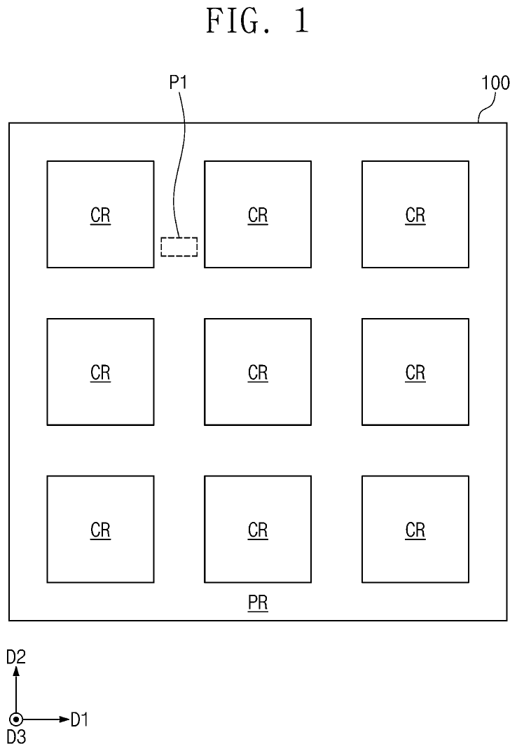

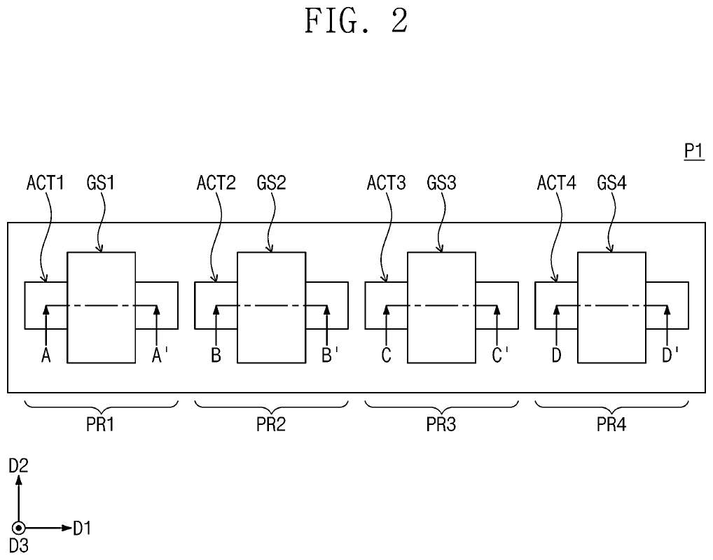

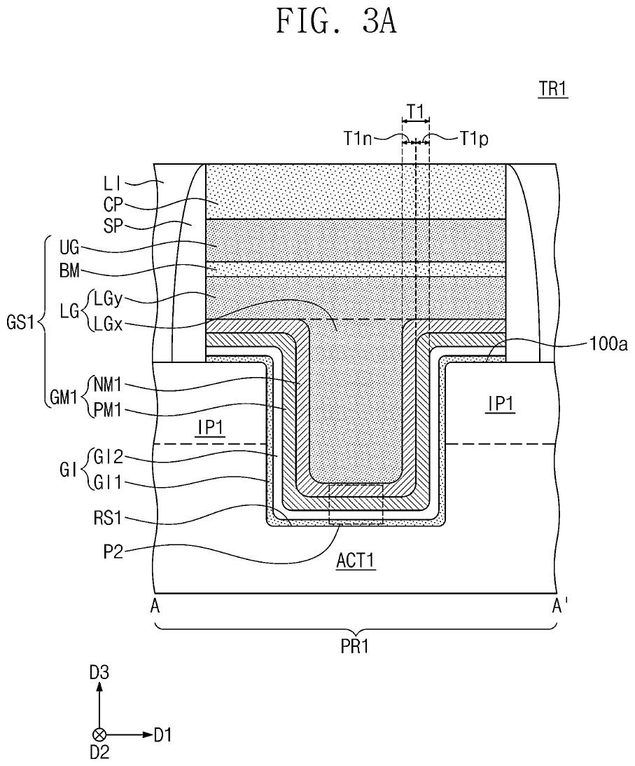

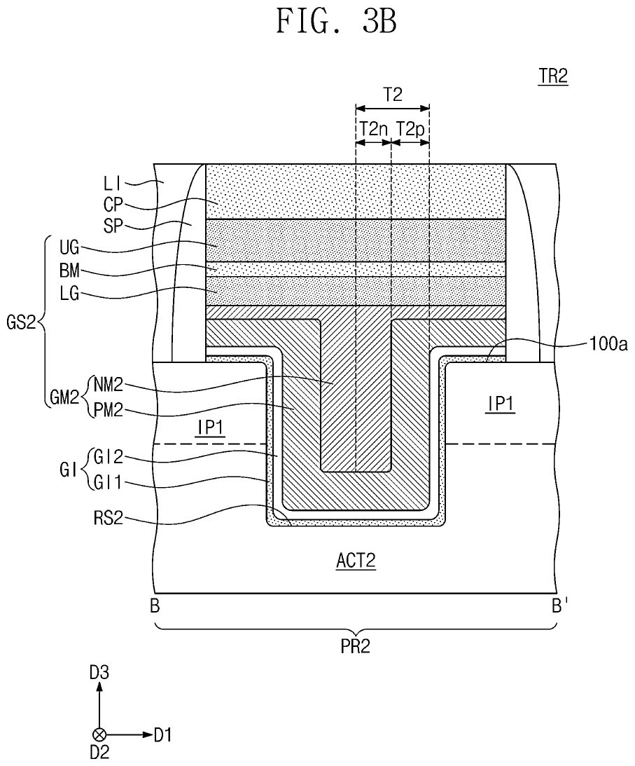

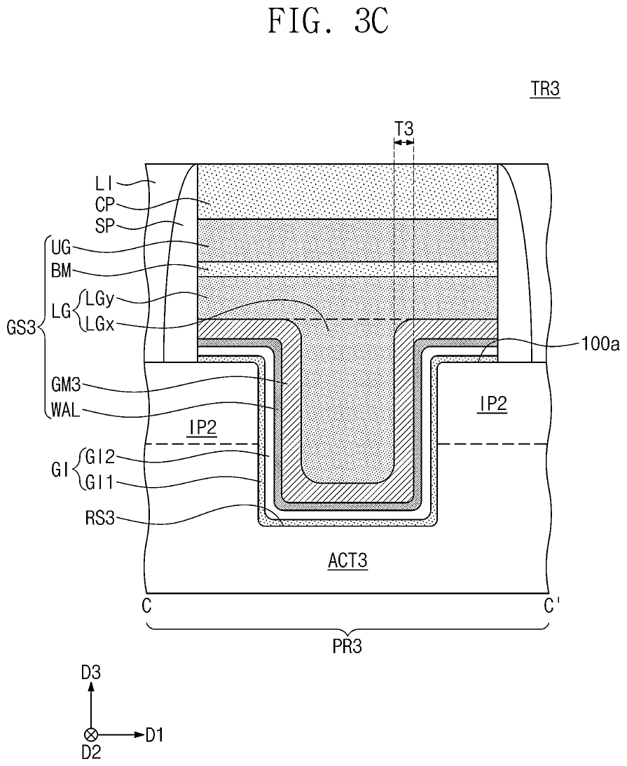

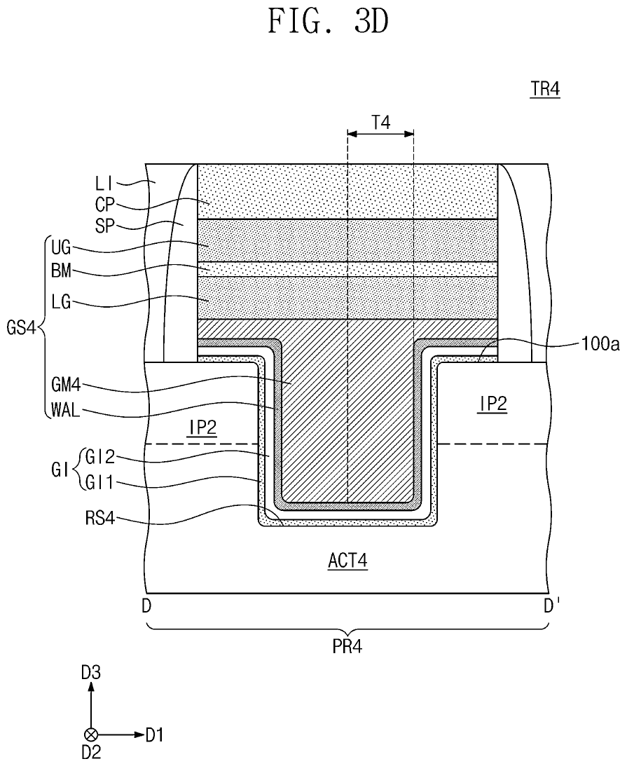

FIG. 1 illustrates a plan view showing a semiconductor device according to some embodiments of the present inventive concepts. FIG. 2 illustrates an enlarged view showing section P1 of FIG. 1. FIGS. 3A, 3B, 3C, and 3D illustrate cross-sectional views respectively taken along lines A-A′, B-B′, C-C′, and D-D′ of FIG. 2.

Referring to FIG. 1, a substrate 100 may include cell areas CR and a peripheral area PR that surrounds the cell areas CR. The term “surround” (or likewise, “cover” or “fill”) as may be used herein may not require completely surrounding (or covering or filling) the described elements or layers, but may, for example, refer to partially surrounding (or covering or filling) the described elements or layers. The cell areas CR may be arranged adjacent to each other in a first direction D1 (e.g., a first horizontal direction) and a second direction D2 (e.g., a second horizontal direction) that are parallel to a bottom surface of the substrate 100. The first direction D1 may intersect the second direction D2. FIG. 1 depicts the cell areas CR are arranged in a 3×3 matrix, but the present inventive concepts are not limited thereto and the number and arrangement of the cell areas CR may be variously changed.

A semiconductor device may be a memory device, and each of the cell areas CR may include a cell circuit such as a memory integrated circuit. The peripheral area PR may include various peripheral circuits required for operation of the cell circuit, and the peripheral circuits may be electrically connected to the cell circuit. The peripheral area PR may include sense amplifier circuits and sub-word line driver circuits. The peripheral area PR may further include a sense amplifier driving power circuit and a ground driver circuit, but the present inventive concepts are not limited thereto.

Referring to FIG. 2, the substrate 100 may include a first peripheral area PR1, a second peripheral area PR2, a third peripheral area PR3, and a fourth peripheral area PR4. The first, second, third, and fourth peripheral areas PR1, PR2, PR3, and PR4 may be portions of the peripheral area PR of the substrate 100. It is illustrated by way of example that the first, second, third, and fourth peripheral areas PR1, PR2, PR3, and PR4 are arranged side by side, but the present inventive concepts are not limited thereto.

Referring to FIGS. 2 and 3A to 3D, the substrate includes a plurality of transistor active regions (described herein by way of example with reference to four transistor active regions, ACT1, ACT2, ACT3, ACT4), generally referred to herein as active regions. In particular, a first active region ACT1, a second active region ACT2, a third active region ACT3, and a fourth active region ACT4 may be respectively provided on the first peripheral area PR1, the second peripheral area PR2, the third peripheral area PR3, and the fourth peripheral area PR4, respectively. The first, second, third, and fourth active regions ACT1, ACT2, ACT3, and ACT4 may be protruding portions of the substrate 100 that protrude along a third direction D3 (e.g., a vertical direction) perpendicular to the bottom surface of the substrate 100.

A device isolation pattern may be provided in the substrate 100, and may define each of the first active region ACT1, the second active region ACT2, the third active region ACT3, and the fourth active region ACT4. For example, the device isolation pattern may include one or more of silicon oxide (SiO₂) and silicon nitride (SiN). The device isolation pattern may be a single layer formed of a single material or a multiple layer formed of two or more materials.

A first recess RS1, a second recess RS2, a third recess RS3, and a fourth recess RS4 may be respectively provided in the first active region ACT1, the second active region ACT2, the third active region ACT3, and the fourth active region ACT4, respectively. An upper portion of the first active region ACT1 may be recessed to define the first recess RS1. An upper portion of the second active region ACT2 may be recessed to define the second recess RS2. An upper portion of the third active region ACT3 may be recessed to define the third recess RS3. An upper portion of the fourth active region ACT4 may be recessed to define the fourth recess RS4.

A gate dielectric pattern GI may conformally extend in or cover each of the first, second, third, and fourth recesses RS1, RS2, RS3, and RS4. As used herein, description of a material or pattern or layer that “conformally covers a recess” or “extends conformally in a recess” may mean that a thickness in a horizontal direction (e.g., D1) of the material or pattern or layer on an inner lateral surface (i.e., a sidewall surface) of the recess is substantially the same as a thickness in a vertical direction (e.g., D3) of the material or pattern or layer on an inner bottom surface of the recess. The gate dielectric pattern GI may extend from an inner lateral surface of each of the first, second, third, and fourth recesses RS1, RS2, RS3, and RS4, thereby covering a top surface 100a of the substrate 100.

The gate dielectric pattern GI may include a first gate dielectric pattern GI1 and a second gate dielectric pattern GI2 that are sequentially conformally cover each of the first, second, third, and fourth recesses RS1, RS2, RS3, and RS4. For example, the first gate dielectric pattern GI1 may include SiON. The second gate dielectric pattern GI2 may include a high-k material. In this description, a high-k material is defined to refer to a material whose dielectric constant is greater than that of silicon oxide. For example, the second gate dielectric pattern GI2 may include one or more of Hf and Zr.

A first gate structure GS1 may run or extend across the first active region ACT1, and a portion of the first gate structure GS1 may be buried in the first recess RS1. A second gate structure GS2 may run or extend across the second active region ACT2, and a portion of the second gate structure GS2 may be buried in the second recess RS2. A third gate structure GS3 may run or extend across the third active region ACT3, and a portion of the third gate structure GS3 may be buried in the third recess RS3. A fourth gate structure GS4 may run or extend across the fourth active region ACT4, and a portion of the fourth gate structure GS4 may be buried in the fourth recess RS4. The first, second, third, and fourth gate structures GS1, GS2, GS3, and GS4 may extend in a horizontal direction (e.g., the second direction D2) parallel to the bottom surface of the substrate 100, and may extend in the same or different directions.

A capping pattern CP may cover a top surface of each of the first, second, third, and fourth gate structures GS1, GS2, GS3, and GS4. For example, the capping pattern CP may include silicon nitride (SiN).

A gate spacer SP may cover a lateral surface of each of each of the first, second, third, and fourth gate structures GS1, GS2, GS3, and GS4. For example, a pair of gate spacers SP may cover opposite lateral surfaces of each of the first, second, third, and fourth gate structures GS1, GS2, GS3, and GS4. The gate spacer SP may be formed of a single layer or multiple layers. The gate spacer SP may include at least one selected from silicon nitride (SiN) and silicon oxide (SiO₂).

The substrate 100 may be provided on its front surface with a lower dielectric layer LI that surrounds and covers the first, second, third, and fourth gate structures GS1, GS2, GS3, and GS4. For example, the lower dielectric layer L1 may include silicon oxide (SiO₂).

First impurity regions IP1 may be provided in the first active region ACT1 and the second active region ACT2. For example, the first impurity regions IP1 may be provided adjacent to opposite sides of the first recess RS1 and opposite sides of the second recess RS2. The first impurity regions IP1 may include p-type impurities.

Second impurity regions IP2 may be provided in the third active region ACT3 and the fourth active region ACT4. For example, the second impurity regions IP2 may be provided adjacent to opposite sides of the third recess RS3 and opposite sides of the fourth recess RS4. The second impurity regions IP2 may include n-type impurities.

Referring to FIGS. 2, 3A, and 3B, first and second active regions ACT1 and ACT2 may be PMOS regions. For example, the first gate structure GS1, the gate dielectric pattern GI, and the first impurity regions IP1 may be collectively used as a first transistor TR1 on the PMOS region. For example, the second gate structure GS2, the gate dielectric pattern GI, and the first impurity regions IP1 may be collectively used as a second transistor TR2 on the PMOS region.

The first gate structure GS1 may include a first gate conductive pattern GM1 that is provided on the gate dielectric pattern GI and conformally covers the first recess RS1. The second gate structure GS2 may include a second gate conductive pattern GM2 that is provided on the gate dielectric pattern GI and conformally covers the second recess RS2. In this description, the phrase “a material (or pattern or layer) fills a recess” may mean that the material or pattern or layer fills an entire inner section of the recess, another component is on an inner surface of the recess and fills a portion of the recess, or the material or pattern or layer fills another portion (e.g., a remaining portion) of the recess. For example, even when the material or pattern or layer fills an entire inner section of the recess or the material or pattern or layer fills another portion (e.g., a remaining portion) of the recess, a seam may be present in the material or pattern or layer.

The first gate conductive pattern GM1 may include a first p-type conductive pattern PM1 and a first n-type conductive pattern NM1 that sequentially conformally cover the first recess RS1. The second gate conductive pattern GM2 may include a second p-type conductive pattern PM2 that conformally covers the second recess RS2 and a second n-type conductive pattern NM2 that fill an unoccupied portion of the second recess RS2. The first p-type conductive pattern PM1 and the first n-type conductive pattern NM1 may extend from the inner lateral surface of the first recess RS1 to cover the top surface 100a of the substrate 100, and the second p-type conductive pattern PM2 and the second n-type conductive pattern NM2 may extend from the inner lateral surface of the second recess RS2 to cover the top surface 100a of the substrate 100. The first and second p-type conductive patterns PM1 and PM2 may include the same material as each other, and the first and second n-type conductive patterns NM1 and NM2 may include the same material as each other. For example, the first and second p-type conductive patterns PM1 and PM2 and the first and second n-type conductive patterns NM1 and NM2 may include one or more of titanium carbide (TiC) and titanium nitride (TiN) that includes C.

The first p-type conductive pattern PM1 may have a first p-thickness T1p in a horizontal or vertical direction on an inner surface of the first recess RS1. The second p-type conductive pattern PM2 may have a second p-thickness T2p in a horizontal or vertical direction on an inner surface of the second recess RS2. The first n-type conductive pattern NM1 may have a first n-thickness T1n in a horizontal or vertical direction on the inner surface of the first recess RS1. The second n-type conductive pattern NM2 may have a second n-thickness T2n in a horizontal or vertical direction on the inner surface of the second recess RS2. The second n-thickness T2n may be defined to refer to a half of a width in the first direction D1 of the second n-type conductive pattern NM2 on the inner lateral surface of the second recess RS2.

The first p-thickness T1p and the first n-thickness T1n may constitute a first thickness T1 of the first gate conductive pattern GM1. The second p-thickness T2p and the second n-thickness T2n may constitute a second thickness T2 of the second gate conductive pattern GM2.

The first gate conductive pattern GM1 may have a first work function, and the second gate conductive pattern GM2 may have a second work function. The first work function may be changed depending on the first thickness T1 of the first gate conductive pattern GM1 formed on the first recess RS1. The second work function may be changed depending on the second thickness T2 of the second gate conductive pattern GM2 formed on the second recess RS2. For example, an increase in the first thickness T1 may induce an increase in the first work function, and an increase in the second thickness T2 may induce an increase in the second work function.

The first thickness T1 of the first gate conductive pattern GM1 may be less than the second thickness T2 of the second gate conductive pattern GM2. For example, the first p-thickness T1p of the first p-type conductive pattern PM1 may be less than the second p-thickness T2p of the second p-type conductive pattern PM2. In addition, the first n-thickness T1n of the first n-type conductive pattern NM1 may be less than the second n-thickness T2n of the second n-type conductive pattern NM2. The difference in thickness may cause the first work function of the first gate conductive pattern GM1 to be less than the second work function of the second gate conductive pattern GM2. As a result, a threshold voltage of the first transistor TR1 may be greater than that of the second transistor TR2.

According to the present inventive concepts, the first thickness T1 of the first gate conductive pattern GM1 may be less than the second thickness T2 of the second gate conductive pattern GM2. The first work function of the first gate conductive pattern GM1 may be less than the second work function of the second gate conductive pattern GM2. Thus, the threshold voltage of the first transistor TR1 may be greater than that of the second transistor TR2. As such, a difference between the first thickness T1 of the first gate conductive pattern GM1 and the second thickness T2 of the second gate conductive pattern GM2 may be adjusted to more easily control a difference in threshold voltage between the first transistor TR1 and the second transistor TR2. Furthermore, unintended changes in the first and second work functions that were achieved based on the first thickness T1 and the second thickness T2 (e.g., changes due to diffusion of a work function material) may be reduced or prevented as described in greater detail below. Accordingly, a semiconductor device may improve in electrical properties.

The first gate structure GS1 may further include a lower gate electrode LG, a barrier pattern BM, and an upper gate electrode UG that are sequentially stacked on the first gate conductive pattern GM1. The second gate structure GS2 may further include a lower gate electrode LG, a barrier pattern BM, and an upper gate electrode UG that are sequentially stacked on the second gate conductive pattern GM2.

The lower gate electrode LG of the first gate structure GS1 may run or extend across the first active region ACT1 and fill an unoccupied portion of the first recess RS1. The lower gate electrode LG may include a lower part LGx that fills an unoccupied portion of the first recess RS1, and may also include an upper part LGy that is provided on the lower part LGx and is not buried in the first recess RS1. As the second gate conductive pattern GM2 fills an unoccupied portion of the second recess RS2, the lower gate electrode LG of the second gate structure GS2 may not be buried in the second recess RS2. For example, the lower gate electrode LG may include one or more of impurity-doped polysilicon and impurity-undoped polysilicon.

The barrier pattern BM may be interposed between the upper gate electrode UG and the lower gate electrode LG. Therefore, a material of the upper gate electrode UG may be prevented from diffusing to the lower gate electrode LG. For example, the barrier pattern BM may include metal nitride (e.g., nitride of one or more of Ti, Mo, W, Cu, Al, Ta, Ru, Ir, and Co).

For example, the upper gate electrode UG may include a metal or metallic material (e.g., Ti, Mo, W, Cu, Al, Ta, Ru, Ir, and Co).

Referring to FIGS. 2, 3C, and 3D, the third and fourth active regions ACT3 and ACT4 may be NMOS regions. For example, the third gate structure GS3, the gate dielectric pattern GI, and the second impurity regions IP2 may be collectively used as a third transistor TR3 on the NMOS region. For example, the fourth gate structure GS4, the gate dielectric pattern GI, and the second impurity regions IP2 may be collectively used as a fourth transistor TR4 on the NMOS region.

The third gate structure GS3 may include a work-function adjustment layer WAL and a third gate conductive pattern GM3 that are provided on the gate dielectric pattern GI and conformally cover the third recess RS3. The fourth gate structure GS4 may include on the gate dielectric pattern GI a work-function adjustment layer WAL that conformally covers the fourth recess RS4 and a fourth gate conductive pattern GM4 that fills an unoccupied portion of the fourth recess RS4.

Lanthanum (La) may be included in the work-function adjustment layer WAL of each of the third and fourth gate structures GS3 and GS4. The work-function adjustment layer WAL may extend from the inner lateral surface of each of the third recess RS3 and the fourth recess RS4, thereby covering the top surface 100a of the substrate 100. The third and fourth gate conductive patterns GM3 and GM4 may include the same material as that of the first and second n-type conductive patterns NM1 and NM2.

The third gate conductive pattern GM3 may have a third thickness T3 in a horizontal or vertical direction on an inner surface of the third recess RS3. The fourth gate conductive pattern GM4 may have a fourth thickness T4 in a horizontal direction on the inner lateral surface of the fourth recess RS4. The fourth thickness T4 may be defined to refer to a half of a width in the first direction D1 of the fourth gate conductive pattern GM4 on the inner lateral surface of the fourth recess RS4.

The third gate conductive pattern GM3 may have a third work function, and the fourth gate conductive pattern GM4 may have a fourth work function. The third work function may be changed depending on the third thickness T3 of the third gate conductive pattern GM3 formed on the third recess RS3. The fourth work function may be changed depending on the fourth thickness T4 of the fourth gate conductive pattern GM4 formed on the fourth recess RS4. For example, an increase in the third thickness T3 may induce an increase in the third work function, and an increase in the fourth thickness T4 may include an increase in the fourth work function.

The third thickness T3 of the third gate conductive pattern GM3 may be less than the fourth thickness T4 of the fourth gate conductive pattern GM4. The difference in thickness may cause the third work function of the third gate conductive pattern GM3 to be less than the fourth work function of the fourth gate conductive pattern GM4. As a result, a threshold voltage of the third transistor TR3 may be less than that of the fourth transistor TR4.

The third gate structure GS3 may further include a lower gate electrode LG, a barrier pattern BM, and an upper gate electrode UG that are sequentially stacked on the third gate conductive pattern GM3. The fourth gate structure GS4 may further include a lower gate electrode LG, a barrier pattern BM, and an upper gate electrode UG that are sequentially stacked on the fourth gate conductive pattern GM4.

The lower gate electrode LG, the barrier pattern BM, and the upper gate electrode UG of each of the third and fourth gate structures GS3 and GS4 may include the same materials as those of the lower gate electrode LG, the barrier pattern BM, and the upper gate electrode UG discussed with reference to FIGS. 3A and 3B.

The lower gate electrode LG of the third gate structure GS3 may have features the same as or similar to those of the lower gate electrode LG of the first gate structure GS1.

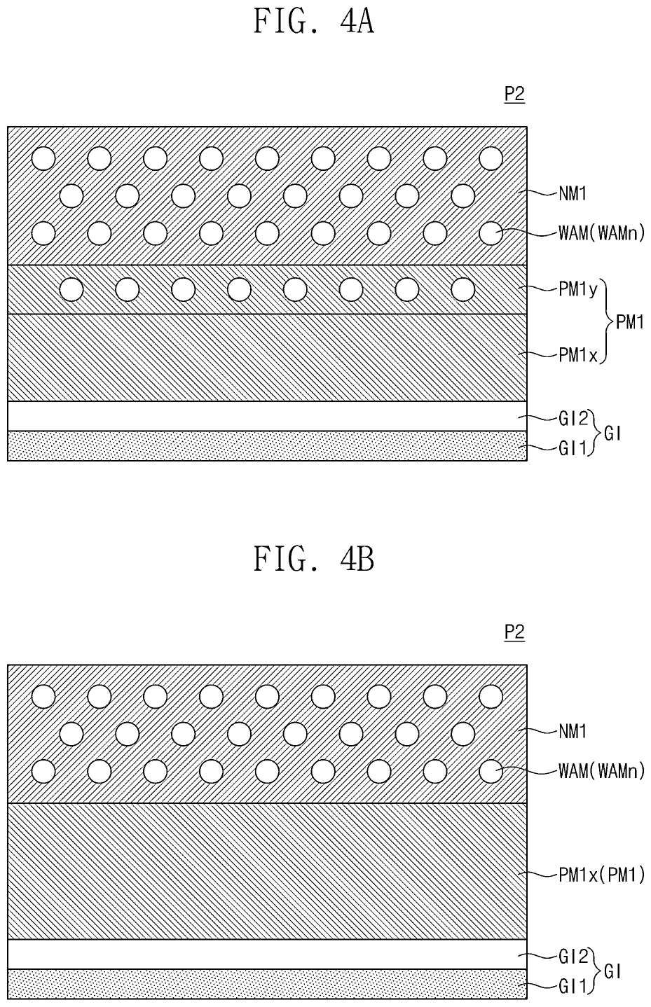

FIGS. 4A and 4B illustrate enlarged views showing section P2 of FIG. 3A.

Referring to FIGS. 4A and 4B, a work-function adjustment material WAM may be provided in the first gate structure GS1. For example, the work-function adjustment material WAM may include one or more of an n-type work-function adjustment material WAMn including La and a p-type work-function adjustment material (not shown) including Al. When the work-function adjustment material WAM diffuses from the first gate structure GS1 to be trapped in the gate dielectric pattern GI, the work-function adjustment material WAM may adjust the first work function of the first gate conductive pattern GM1 of the first gate structure GS1.

The first n-type conductive pattern NM1 may include the n-type work-function adjustment material WAMn. For example, the n-type work-function adjustment material WAMn may be uniformly distributed in the first n-type conductive pattern NM1, but the present inventive concepts are not limited thereto. For another example, the n-type work-function adjustment material WAMn may be more distributed (e.g., may have a lower concentration or density) in a portion of the first n-type conductive pattern NM1 adjacent to the first p-type conductive pattern PM1.

The first p-type conductive pattern PM1 may include one or more of TiC and TiN that includes C. The carbon (C) in the first p-type conductive pattern PM1 may reduce or prevent the n-type work-function adjustment material WAMn from diffusing from the first n-type conductive pattern NM1 to the gate dielectric pattern GI. As a result, as shown in FIG. 4A, the first p-type conductive pattern PM1 may be divided into a first region PM1x that does not include (i.e., is free of) the n-type work-function adjustment material WAMn and a second region PM1y that includes the n-type work-function adjustment material WAMn. The second region PM1y may be closer to the first region PM1x than the first n-type conductive pattern NM1 (e.g., the second region PM1y may be between the first region PM1x and the first n-type conductive pattern NM1). For example, when viewed in a direction perpendicular to an interface between the first n-type conductive pattern NM1 and the first p-type conductive pattern PM1, a thickness of the first region PM1x may be greater than that of the second region PM1y, but the present inventive concepts are not limited thereto. Alternatively, as shown in FIG. 4B, the first p-type conductive pattern PM1 may have only a first region PM1x that does not include or is free of the n-type work-function adjustment material WAMn.

According to the present inventive concepts, the carbon (C) in the first p-type conductive pattern PM1 may reduce or prevent the n-type work-function adjustment material WAMn from diffusing from the first n-type conductive pattern NM1 to the gate dielectric pattern GI. For example, at least a portion of the first p-type conductive pattern PM1 (e.g., the first region PM1x) along an interface IF with the gate dielectric pattern GI may be free of the n-type work-function adjustment material WAMn. As a result, the n-type work-function adjustment material WAMn may not be trapped in the gate dielectric pattern GI, and the first work function of the first p-type conductive pattern PM1 targeted through the first thickness T1 may not be unnecessarily changed (i.e., may not be unintentionally altered, for example, due to diffusion of a work adjustment material WAM). Therefore, as the threshold voltage of the first transistor TR1 is not unintentionally or unnecessarily changed by the n-type work-function adjustment material WAMn, a semiconductor device may improve in reliability and electrical properties.

The first p-type conductive pattern PM1 may not include the p-type work-function adjustment material (e.g., Al). When the first p-type conductive pattern PM1 includes the p-type work-function adjustment material, the p-type work-function adjustment material may be trapped in the gate dielectric pattern GI. Therefore, the p-type work-function adjustment material may unintentionally or unnecessarily change a value of the first work function that is targeted through the first thickness T1.

In addition, when the p-type work-function adjustment material is trapped in the gate dielectric pattern GI, when the first transistor TR1 is turned on, a value of current flowing through the first transistor TR1 may decrease, and electrical properties of a semiconductor device may be reduced or worsened.

Alternatively, according to the present inventive concepts of the present inventive concepts, the first p-type conductive pattern PM1 may not include the p-type work-function adjustment material (e.g., Al). For example, at least a portion of the first p-type conductive pattern PM1 along an interface IF with the gate dielectric pattern GI may be free of the p-type work-function adjustment material. Therefore, the p-type work-function adjustment material may not diffuse from the first p-type conductive pattern PM1 to the gate dielectric pattern GI, and may not be trapped in the gate dielectric pattern GI. In conclusion, the threshold voltage of the first transistor TR1 targeted through the first thickness T1 may not be unintentionally or unnecessarily changed by the p-type work-function adjustment material. In addition, when the first transistor TR1 is turned on, a flowing current may not be affected by the p-type work-function adjustment material, and as a result there may be an increase in current flowing through the first transistor TR1. Accordingly, electrical properties of a semiconductor device may be improved.

A description of features of the first p-type conductive pattern PM1 discussed with reference to FIGS. 4A and 4B may be identical or similar to features of the second p-type conductive pattern PM2.

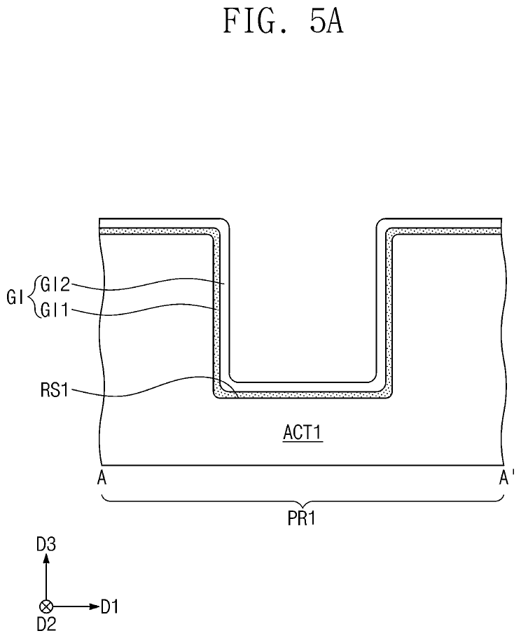

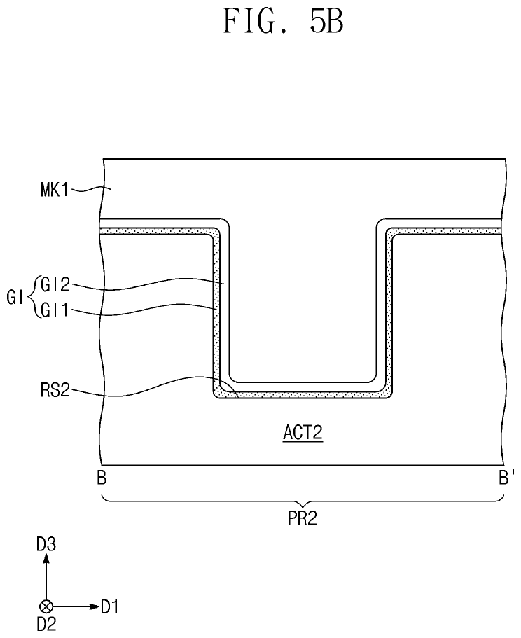

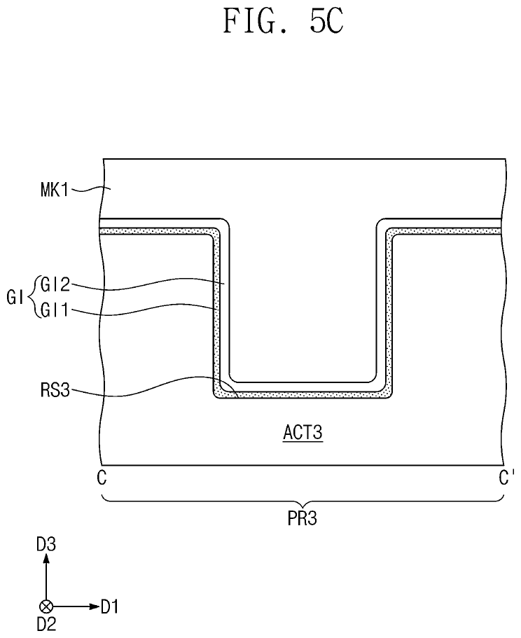

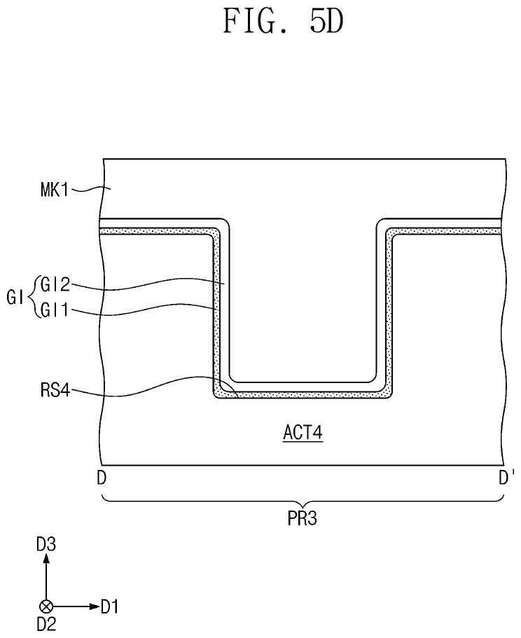

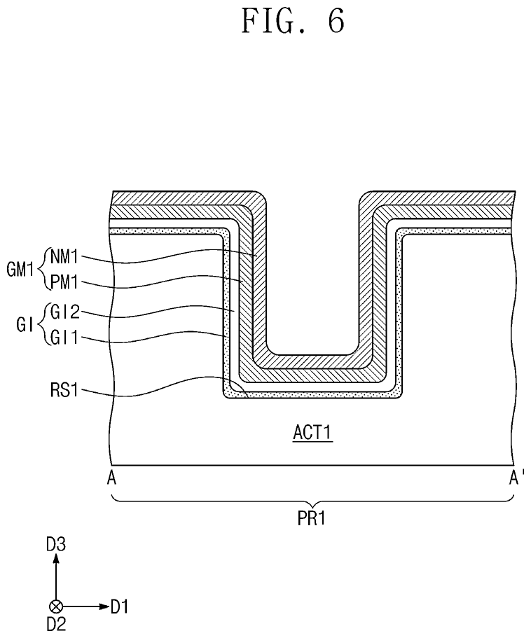

With reference to FIGS. 5A to 10D, the following will describe a method of fabricating a semiconductor device according to some embodiments of the present inventive concepts. For brevity of description, an explanation of components repetitive to those discussed above will be omitted, and a difference thereof will be discussed in detail.

FIGS. 5A to 5D illustrate diagrams showing a method of fabricating a semiconductor device according to some embodiments of the present inventive concepts.

Referring to FIGS. 2 and 5A to 5D, a substrate 100 may be provided which includes a peripheral area PR. First, second, third, and fourth active regions ACT1, ACT2, ACT3, and ACT4 may be respectively formed on first, second, third, and fourth peripheral areas PR1, PR2, PR3, and PR4. A device isolation pattern may be formed to cover each of the first, second, third, and fourth active regions ACT1, ACT2, ACT3, and ACT4.

First, second, third, and fourth recesses RS1, RS2, RS3, and RS4 may be formed on upper portions of the first, second, third, and fourth active regions ACT1, ACT2, ACT3, and ACT4, respectively. For example, the first, second, third, and fourth recesses RS1, RS2, RS3, and RS4 may be formed at the same time.

A gate dielectric pattern GI may be formed on each of the first, second, third, and fourth recesses RS1, RS2, RS3, and RS4. The formation of the gate dielectric pattern GI may include sequentially forming first and second gate dielectric patterns GI1 and GI2 on an inner surface of each of the first, second, third, and fourth recesses RS1, RS2, RS3, and RS4. For example, the first and second gate dielectric patterns GI1 and GI2 may be formed to sequentially conformally cover each of the first, second, third, and fourth recesses RS1, RS2, RS3, and RS4.

A first mask pattern MK1 may be formed on each of the second, third, and fourth active regions ACT2, ACT3, and ACT4. The first mask pattern MK1 may fill each of the second, third, and fourth active regions ACT2, ACT3, and ACT4. The first mask pattern MK1 may not be formed on the first active region ACT1 and may not cover the first recess RS1.

Referring to FIGS. 2 and 6, a first p-type conductive pattern PM1 may be formed on the second gate dielectric pattern GI2 and to conformally cover the first recess RS1. For example, the first p-type conductive pattern PM1 may be formed by an atomic layer deposition (ALD) process.

Afterwards, on the first p-type conductive pattern PM1, a work-function adjustment layer (not shown) and a first preliminary n-type conductive pattern (not shown) may be formed to sequentially conformally cover the first recess RS1. For example, an atomic layer deposition (ALD) process may be performed to form the work-function adjustment layer and the first preliminary n-type conductive pattern. The work-function adjustment layer may include a work-function adjustment material discussed with reference to FIGS. 4A and 4B.

When the first preliminary n-type conductive pattern is formed after the formation of the work-function adjustment layer, the work-function adjustment layer may diffuse into the first preliminary n-type conductive pattern. Therefore, the work-function adjustment layer and the first preliminary n-type conductive pattern may not be distinguished from each other, and may constitute a first n-type conductive pattern NM1. The diffusion of the work-function adjustment layer may cause the first n-type conductive pattern NM1 to include the work-function adjustment material.

For example, the work-function adjustment material may also partially diffuse to the first p-type conductive pattern PM1, and thus as discussed with reference to FIG. 4A, the first p-type conductive pattern PM1 may be divided into a first region PM1x and a second region PM1y. Even when the work-function adjustment material diffuses to the first p-type conductive pattern PM1 (i.e., into the second region PM1y of the first p-type conductive pattern PM1), the first region PM1x of the first p-type conductive pattern PM1 may separate the work-function adjustment material from the gate dielectric pattern GI. That is, the first region PM1x of the first p-type conductive pattern PM1 may be free of the work-function adjustment material.

Alternatively, the first p-type conductive pattern PM1 may inhibit the diffusion of the work-function adjustment material. Therefore, as discussed with reference to FIG. 4B, the first p-type conductive pattern PM1 may have only the first region PM1x, which may be free of the work function adjustment material.

The first p-type conductive pattern PM1 and the first n-type conductive pattern NM1 may constitute a first gate conductive pattern GM1. The first mask pattern MK1 may prevent the first gate conductive pattern GM1 from being formed on each of the second, third, and fourth active regions ACT2, ACT3, and ACT4.

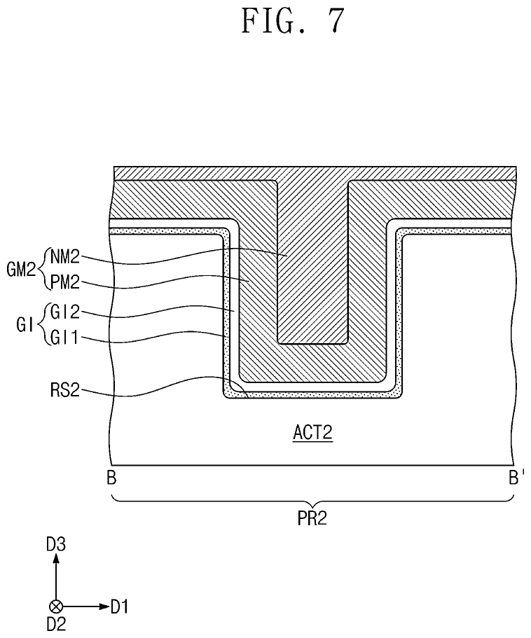

Referring to FIGS. 2 and 7, the first mask pattern MK1 may be removed from the substrate 100. Afterwards, a second mask pattern (not shown) may be formed on each of the first active region ACT1, the third active region ACT3, and the fourth active region ACT4. The second mask pattern may fill each of the first recess RS1, the third recess RS3, and the fourth recess RS4. The second mask pattern may not be formed on the second active region ACT2, and may not cover the second recess RS2.

On the second gate dielectric pattern GI2, a second p-type conductive pattern PM2 may be formed to conformally cover the second recess RS2. For example, the second p-type conductive pattern PM2 may be formed by an atomic layer deposition (ALD) process.

On the second p-type conductive pattern PM2, a work-function adjustment layer (not shown) may be formed to conformally cover the second recess RS2. Thereafter, on the work-function adjustment layer, a second preliminary n-type conductive pattern may be formed to fill an unoccupied portion of the second recess RS2. For example, the work-function adjustment layer may be formed by an atomic layer deposition (ALD) process, and the second preliminary n-type conductive pattern may be formed by a chemical vapor deposition (CVD) process. The work-function adjustment layer may include a work-function adjustment material discussed with reference to FIGS. 4A and 4B.

When the second preliminary n-type conductive pattern is formed after the formation of the work-function adjustment layer, the work-function adjustment layer may diffuse into the second preliminary n-type conductive pattern. Therefore, the work-function adjustment layer and the second preliminary n-type conductive pattern may not be distinguished from each other, and may collectively constitute a second n-type conductive pattern NM2. The diffusion of the work-function adjustment layer may cause the second n-type conductive pattern NM2 to include the work-function adjustment material.

The relationship between the second p-type conductive pattern PM2 and the work-function adjustment material may be the same as that between the first p-type conductive pattern PM1 and the work-function adjustment material discussed above with reference to FIGS. 2 and 6.

The second p-type conductive pattern PM2 and the second n-type conductive pattern NM2 may constitute a second gate conductive pattern GM2. The second mask pattern may prevent the second gate conductive pattern GM2 from being formed on each of the first active region ACT1, the third active region ACT3, and the fourth active region ACT4.

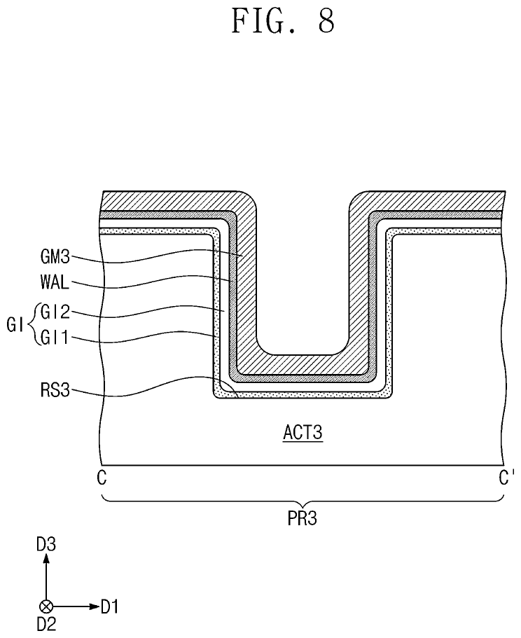

Referring to FIGS. 2 and 8, the second mask pattern may be removed from the substrate 100. Afterwards, a third mask pattern (not shown) may be formed on each of the first active region ACT1, the second active region ACT2, and the fourth active region ACT4. The third mask pattern may fill each of the first recess RS1, the second recess RS2, and the fourth recess RS4. The third mask pattern may not be formed on the third active region ACT3, and may not cover the third recess RS3.

On the second gate dielectric pattern GI2, a work-function adjustment layer WAL and a third gate conductive pattern GM3 may be formed to sequentially conformally cover the third recess RS3. For example, an atomic layer deposition (ALD) process may be used to form each of the work-function adjustment layer WAL and the third gate conductive pattern GM3.

The third mask pattern may prevent the third gate conductive pattern GM3 from being formed on each of the first active region ACT1, the second active region ACT2, and the fourth active region ACT4.

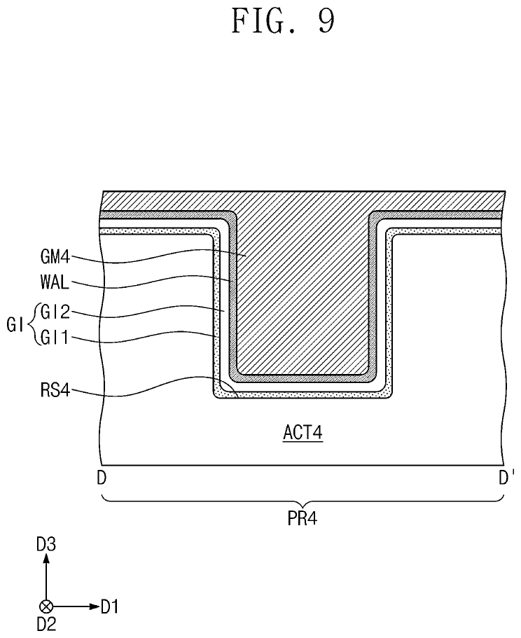

Referring to FIGS. 2 and 9, the third mask pattern may be removed from the substrate 100. Afterwards, a fourth mask pattern (not shown) may be formed on each of the first, second, and third active regions ACT1, ACT2, and ACT3. The fourth mask pattern may fill each of the first, second, and third recesses RS1, RS2, and RS3. The fourth mask pattern may not be formed on the fourth active region ACT4, and may not cover the fourth recess RS4.

On the second gate dielectric pattern GI2, a work-function adjustment layer WAL may be formed to conformally cover the fourth recess RS4. After that, on the work-function adjustment layer WAL, a fourth gate conductive pattern GM4 may be formed to fill an unoccupied portion of the fourth recess RS4. For example, the work-function adjustment layer WAL may be formed by an atomic layer deposition (ALD) process. The fourth gate conductive pattern GM4 may be formed by a chemical vapor deposition (CVD) process. Thereafter, the fourth mask pattern may be removed from the substrate 100.

The fourth mask pattern may prevent the fourth gate conductive pattern GM4 from being formed on each of the first, second, and third active regions ACT1, ACT2, and ACT3.

FIGS. 5A to 9 depict that the first gate conductive pattern GM1, the second conductive pattern GM2, the third gate conductive pattern GM3, and the fourth gate conductive pattern GM4 are sequentially formed on the first active region ACT1, the second active region ACT2, the third active region ACT3, and the fourth active region ACT4, respectively, but the present inventive concepts are not limited thereto. This may be for convenience of description, and the formation sequence of the first, second, third, and fourth gate conductive patterns GM1, GM2, GM3, and GM4 may be changed by one of ordinary skill in the art.

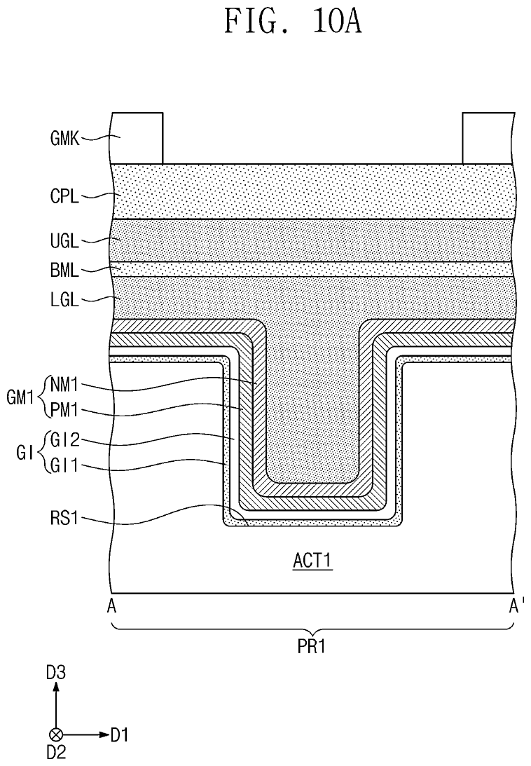

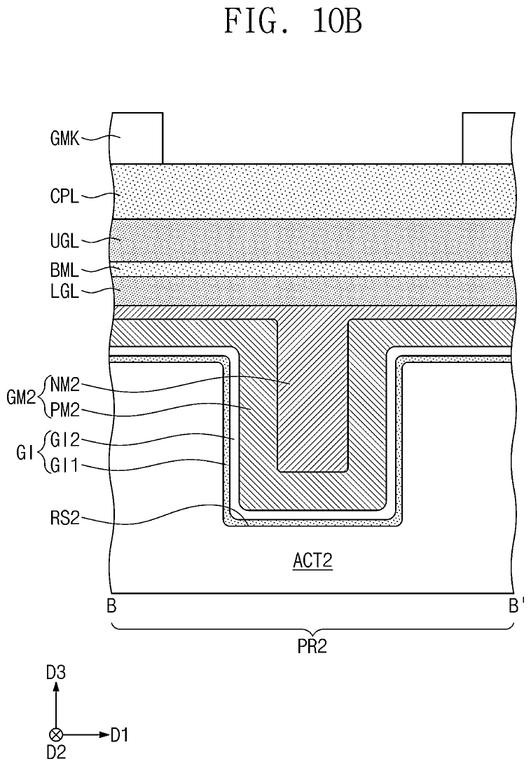

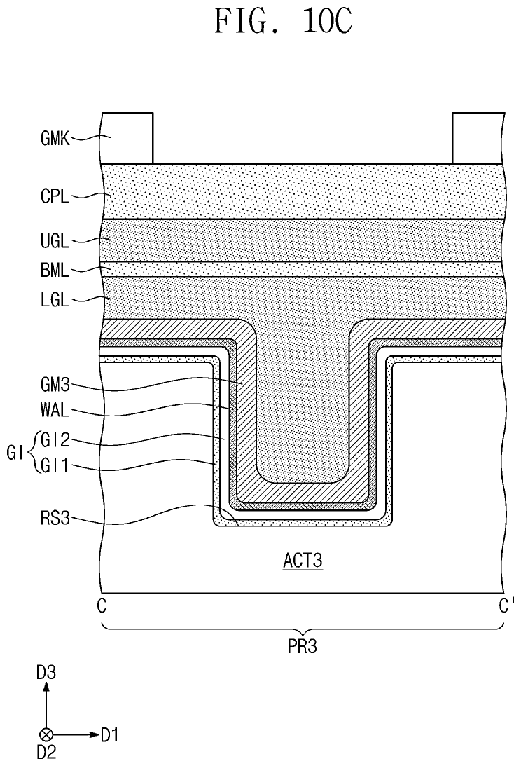

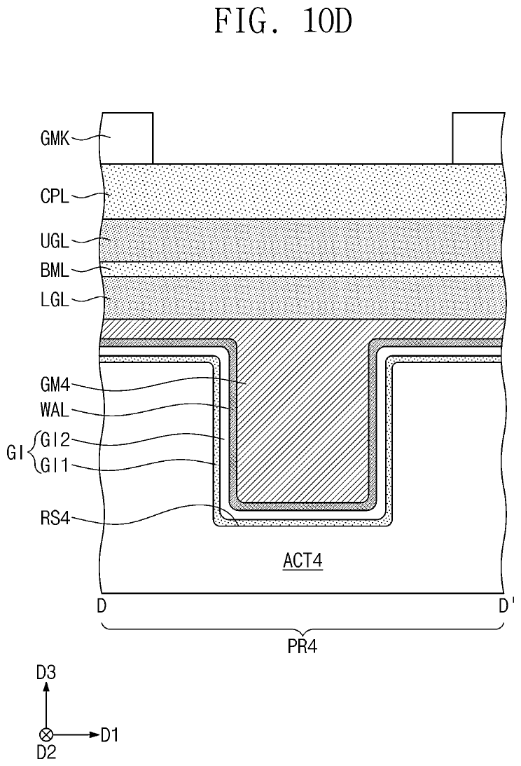

Referring to FIGS. 2 and 10A to 10D, a lower gate electrode layer LGL may be formed to cover a front surface of the substrate 100 on the first, second, third, and fourth active regions ACT1, ACT2, ACT3, and ACT4. In the first and third active regions ACT1 and ACT3, the lower gate electrode layer LGL may be formed to fill an unoccupied portion of each of the first and third recesses RS1 and RS3 and to cover a top surface 100a of the substrate 100.

Afterwards, a barrier layer BML, an upper gate electrode layer UGL, a capping layer CPL, and a gate mask pattern GMK may be formed and sequentially stacked on the lower gate electrode layer LGL.

Referring back to FIGS. 2 and 3A to 3D, a lower gate electrode LG, a barrier pattern BM, an upper gate electrode UG, and a capping pattern CP may be formed by using the gate mask pattern GMK as an etching mask to perform a removal process on a portion of each of the lower gate electrode layer LGL, the barrier layer BML, the upper gate electrode layer UGL, and the capping layer CPL. Therefore, first, second, third, and fourth gate structures GS1, GS2, GS3, and GS4 may be respectively formed on the first, second, third, and fourth active regions ACT1, ACT2, ACT3, and ACT4.

A spacer SP may be formed to cover opposite lateral surfaces of each of the first, second, third, and fourth gate structures GS1, GS2, GS3, and GS4. Then, a lower dielectric layer LI may be formed to surround and cover a lateral surface of each of the first, second, third, and fourth gate structures GS1, GS2, GS3, and GS4.

According to the present inventive concepts, a first thickness of a first gate conductive pattern may be less than a second thickness of a second gate conductive pattern. A first work function of the first gate conductive pattern may be less than a second work function of the second gate conductive pattern, based on the first and second thicknesses thereof. As a result, a threshold voltage of a first transistor may be greater than that of a second transistor. A difference between the first thickness of the first gate conductive pattern and the second thickness of the second gate conductive pattern may be adjusted to more easily control a difference in threshold voltage between the first transistor and the second transistor. Accordingly, a semiconductor device may improve in electrical properties.

According to the present inventive concepts, carbon (C) in a first p-type conductive pattern may prevent an n-type work-function adjustment material from diffusing from a first n-type conductive pattern to a gate dielectric pattern. As such, at least a portion of the first p-type conductive pattern may be free of the n-type work adjustment material along an interface with the gate dielectric pattern. As a result, the n-type work-function adjustment material may not be trapped in the gate dielectric pattern, and a first work function of the first p-type conductive pattern targeted through the first thickness may not be unintentionally or unnecessarily changed. Therefore, as the threshold voltage of the first transistor is not unintentionally or unnecessarily changed by the n-type work-function adjustment material, reliability and electrical properties of a semiconductor device may be improved.

According to the present inventive concepts, the first p-type conductive pattern may not include a p-type work-function adjustment material (e.g., Al). As such, at least a portion of the first p-type conductive pattern may be free of the p-type work adjustment material along an interface with the gate dielectric pattern. Therefore, the p-type work-function adjustment material may not diffuse from the first p-type conductive pattern to the gate dielectric pattern, and may not be trapped in the gate dielectric pattern. As a result, the threshold voltage of the first transistor targeted through the first thickness may not be unintentionally or unnecessarily changed by the p-type work-function adjustment material. In addition, when the first transistor is turned on, a flowing current may not be affected by the p-type work-function adjustment material, and as a result there may be an increase in current flowing through the first transistor. Accordingly, electrical properties of a semiconductor device may be improved.

The aforementioned description provides some embodiments for explaining the present inventive concepts. Therefore, the present inventive concepts are not limited to the embodiments described above, and it will be understood by one of ordinary skill in the art that variations in form and detail may be made therein without departing from the scope of the present inventive concepts.

What is claimed is:

1. A semiconductor device, comprising:
a substrate comprising a first active region and a second active region;
a first gate conductive pattern that extends conformally in a first recess in the first active region; and
a second gate conductive pattern that at least partially fills a second recess in the second active region,
wherein the first gate conductive pattern has a first thickness in a horizontal direction on an inner lateral surface of the first recess,
wherein the second gate conductive pattern has a second thickness in the horizontal direction on an inner lateral surface of the second recess, and
wherein the first thickness is less than the second thickness.

2. The semiconductor device of claim 1, wherein a first work function of the first gate conductive pattern is less than a second work function of the second gate conductive pattern.

3. The semiconductor device of claim 1, wherein each of the first and second gate conductive patterns includes one or more of titanium carbide (TiC) and titanium nitride (TiN) that includes carbon (C).

4. The semiconductor device of claim 1, wherein:
the first gate conductive pattern comprises a first p-type conductive pattern and a first n-type conductive pattern that are sequentially stacked and extend conformally in the first recess; and
the second gate conductive pattern comprises a second p-type conductive pattern that extends conformally in the second recess and a second n-type conductive pattern that is on the second p-type conductive pattern and at least partially fills a portion of the second recess that is unoccupied by the second p-type conductive pattern.

5. The semiconductor device of claim 4, wherein:
the first p-type conductive pattern has a first p-thickness in the horizontal direction on the inner lateral surface of the first recess;
the second p-type conductive pattern has a second p-thickness in the horizontal direction on the inner lateral surface of the second recess; and
the first p-thickness is less than the second p-thickness.

6. The semiconductor device of claim 4, wherein:
the first n-type conductive pattern has a first n-thickness in the horizontal direction on the inner lateral surface of the first recess;
the second n-type conductive pattern has a second n-thickness in the horizontal direction on the inner lateral surface of the second recess; and
the first n-thickness is less than the second n-thickness.

7. The semiconductor device of claim 4, further comprising:
a gate dielectric pattern between the first recess and the first gate conductive pattern and
between the second recess and the second gate conductive pattern,
wherein each of the first and second n-type conductive patterns includes a work function adjustment material, and
wherein the first and second p-type conductive patterns separate the first and second n-type conductive patterns from the gate dielectric pattern, respectively, and at least a portion of each of the first and second p-type conductive patterns is free of the work-function adjustment material.

8. The semiconductor device of claim 1, further comprising:
a first gate dielectric pattern between the first recess and the first gate conductive pattern; and
a second gate dielectric pattern between the second recess and the second gate conductive pattern,
wherein the first and second gate dielectric patterns include a high-k material.

9. The semiconductor device of claim 8, wherein the first and second gate dielectric patterns are free of one or more of lanthanum (La) and aluminum (Al).

10. The semiconductor device of claim 1, further comprising:
a lower gate electrode on the first gate conductive pattern,
wherein the lower gate electrode at least partially fills the first recess.

11. The semiconductor device of claim 1, wherein the substrate further comprises a third active region and a fourth active region, and the semiconductor device further comprises:
a third gate conductive pattern that extends conformally in a third recess in the third active region; and
a fourth gate conductive pattern that at least partially fills a fourth recess in the fourth active region,
wherein the third gate conductive pattern has a third thickness in the horizontal direction on an inner lateral surface of the third recess,
wherein the fourth gate conductive pattern has a fourth thickness in the horizontal direction on an inner lateral surface of the fourth recess, and
wherein the third thickness is less than the fourth thickness.

12. The semiconductor device of claim 11, wherein a third work function of the third gate conductive pattern is less than a fourth work function of the fourth gate conductive pattern.

13. A semiconductor device, comprising:
a substrate comprising a first active region and a second active region;
a first gate conductive pattern that extends conformally in a first recess of the first active region; and
a second gate conductive pattern that at least partially fills a second recess of the second active region,
wherein the first gate conductive pattern comprises a first p-type conductive pattern and a first n-type conductive pattern that are sequentially stacked and extend conformally in the first recess,
wherein the second gate conductive pattern comprises a second p-type conductive pattern that extends conformally in the second recess of the second active region and a second n-type conductive pattern that is on the second p-type conductive pattern and at least partially fills a portion of the second recess that is unoccupied by the second p-type conductive pattern, and
wherein a first work function of the first gate conductive pattern is less than a second work function of the second gate conductive pattern.

14. The semiconductor device of claim 13, wherein each of the first and second gate conductive patterns includes one or more of titanium carbide (TiC) and titanium nitride (TiN) that includes carbon (C).

15. The semiconductor device of claim 13, further comprising:
a gate dielectric pattern between the first recess and the first gate conductive pattern and
between the second recess and the second gate conductive pattern,
wherein each of the first and second n-type conductive patterns includes a work-function adjustment material,
wherein the first and second p-type conductive patterns separate the first and second n-type conductive patterns from the gate dielectric patterns, respectively, and at least a portion of each of the first and second p-type conductive patterns is free of the work-function adjustment material.

16. The semiconductor device of claim 13, further comprising:
a lower gate electrode on the first gate conductive pattern,
wherein the lower gate electrode at least partially fills the first recess.

17. The semiconductor device of claim 13, wherein the substrate further comprises a third active region and a fourth active region, and the semiconductor device further comprises:
a third gate conductive pattern that extends conformally in a third recess in the third active region; and
a fourth gate conductive pattern that at least partially fills a fourth recess in the fourth active region,
wherein the third gate conductive pattern has a third thickness in a horizontal direction on an inner lateral surface of the third recess,
wherein the fourth gate conductive pattern has a fourth thickness in the horizontal direction on an inner lateral surface of the fourth recess, and
wherein the third thickness is less than the fourth thickness.

18. A semiconductor device, comprising:
a substrate comprising a cell area and a peripheral area, the substrate comprising a first active region and a second active region on the peripheral area;
a first gate conductive pattern that extends conformally in a first recess in the first active region;
a second gate conductive pattern that at least partially fills a second recess in the second active region;
first and second lower gate electrodes on the first and second gate conductive patterns, respectively;
first and second upper gate electrodes on the first and second lower gate electrodes, respectively;
first and second barrier patterns between the first and second lower gate electrodes and the first and second upper gate electrodes, respectively; and
first and second capping patterns on top surfaces of the first and second upper gate electrodes, respectively
wherein the first gate conductive pattern has a first thickness in a horizontal direction on an inner lateral surface of the first recess,
wherein the second gate conductive pattern has a second thickness in the horizontal direction on an inner lateral surface of the second recess, and
wherein the first thickness is less than the second thickness.

19. The semiconductor device of claim 18, wherein a first work function of the first gate conductive pattern is less than a second work function of the second gate conductive pattern.

20. The semiconductor device of claim 18, wherein the substrate further comprises a third active region and a fourth active region, and the semiconductor device further comprises:
a third gate conductive pattern that extends conformally in a third recess in the third active region; and
a fourth gate conductive pattern that at least partially fills a fourth recess in the fourth active region,
wherein the third gate conductive pattern has a third thickness in the horizontal direction on an inner lateral surface of the third recess,
wherein the fourth gate conductive pattern has a fourth thickness in the horizontal direction on an inner lateral surface of the fourth recess, and
wherein the third thickness is less than the fourth thickness.
